(19) United States
(12) Patent Application Publication
(10) Pub. No.: US 2015/0311875 A1
(43) Pub. Date: Oct. 29, 2015

(54) SENSE AMPLIFIER WITH IMPROVED RESOLVING TIME

(71) Applicant: QUALCOMM Incorporated, San Diego, CA (US)

(72) Inventors: Nan Chen, San Diego, CA (US); Yu Song, San Diego, CA (US); Terrence Brian Remple, San Diego, CA (US); Yuehchun Claire Cheng, San Diego, CA (US)

(73) Assignee: QUALCOMM Incorporated, San Diego, CA (US)

(21) Appl. No.: 14/261,161

(22) Filed: Apr. 24, 2014

(51) Int. Cl. H03F 3/45

(52) U.S. Cl. CPC H03F 3/45076

(57) ABSTRACT

Sense amplifiers that can provide improved resolving times can be used, for example, in clock and data recovery circuits. The sense amplifiers sense the value of a differential input signal using a latch circuit and then, after an initial sensing time, force the latch circuit to resolve a digital value that corresponds to the value of the input signal. An implementation of the sense amplifies uses a first latch with cross-coupled inverters that produce set and reset signals. A transistor pair couples the differential input signal to the cross-coupled inverters via a switch to ground. A discharge path circuit arranged to accelerate the resolving of the latch circuit is also coupled to the cross-coupled inverters. The discharge path can be enabled after an initial sensing time.

### BACKGROUND

1. Field

The present invention relates to electronic sense amplifiers and, more particularly, to sense amplifiers with improved resolving times.

2. Background

As power supply voltages drop with technology scaling, CMOS latches switch slower. Switching of the latches can be particularly slow when the power supply is approximately equal to the sum of the threshold voltages of the n-channel and p-channel transistors. Slow latch switching can slow down the resolving time in CMOS sense amplifiers. Slow resolving time in a sense amplifier causes a high probability of metastable states and circuit errors. The problem can be particularly troublesome when the sense amplifier is used in a low-voltage, high-speed, mixed-signal circuit. For example, a clock and data recovery (CDR) circuit may experience an increased rate of bit errors. CDR circuits are used, for example, in Universal Serial Bus (USB), High-Definition Multimedia Interface (HDMI), Serial Advanced Technology Attachment (SATA), and Peripheral Component Interconnect Express (PCIe) interfaces.

### SUMMARY

In one aspect, a sense amplifier is provided that includes: a first latch comprising a first inverter having an output coupled to a set signal and an input coupled to a reset signal and a second inverter having an output coupled to the reset signal and an input coupled to the set signal; a first transistor pair having gates coupled to a differential input signal, having drains coupled to the first latch, and having sources coupled to a first common node; a first switch coupled between the first common node and a ground reference, wherein the first switch is configured to be turned off during a precharge phase of the sense amplifier and turned on during a resolving phase of the sense amplifier; and a discharge path circuit coupled to the drains of the first transistor pair and configured to accelerate the resolving phase of the sense amplifier.

In one aspect, a method sensing an input signal is provided. The method includes: sensing a value of the input signal using a latch circuit; and forcing, after an initial sensing time, the latch circuit to resolve a digital value.

In one aspect, a sense amplifier is provided that includes: a first latch comprising a first inverter and a second inverter having an output coupled to a reset signal and an input of the first inverter and an input coupled to a set signal and an output of the first inverter; a second latch having an output coupled to the output of the sense amplifier, the second latch being set by the set signal and reset by the reset signal; a first transistor pair having gates coupled to the differential input signal of the sense amplifier, having drains coupled to the first latch, and having sources coupled to a common node; a first switch coupled between the common node and a ground reference, wherein the first switch is configured to be turned off during a precharge phase of the sense amplifier and turned on during a resolving phase of the sense amplifier; and a means for accelerating the resolving phase of the sense amplifier.

Other features and advantages of the present invention should be apparent from the following description which illustrates, by way of example, aspects of the invention.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 is a functional block diagram of a clock and data recovery circuit;

FIG. 2 is a waveform diagram illustrating operation of the clock and data recovery circuit of FIG. 1;

FIG. 3 is a schematic diagram of a sense amplifier according to a presently disclosed embodiment;

FIG. 4 is a schematic diagram of another sense amplifier according to a presently disclosed embodiment;

FIG. 5 is a schematic diagram of another sense amplifier according to a presently disclosed embodiment;

FIG. 6 is a schematic diagram of another sense amplifier according to a presently disclosed embodiment; and

FIG. 7 is a flowchart of a process for sensing an input signal according to a presently disclosed embodiment.

### DETAILED DESCRIPTION

The detailed description set forth below, in connection with the accompanying drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in simplified form in order to avoid obscuring such concepts.

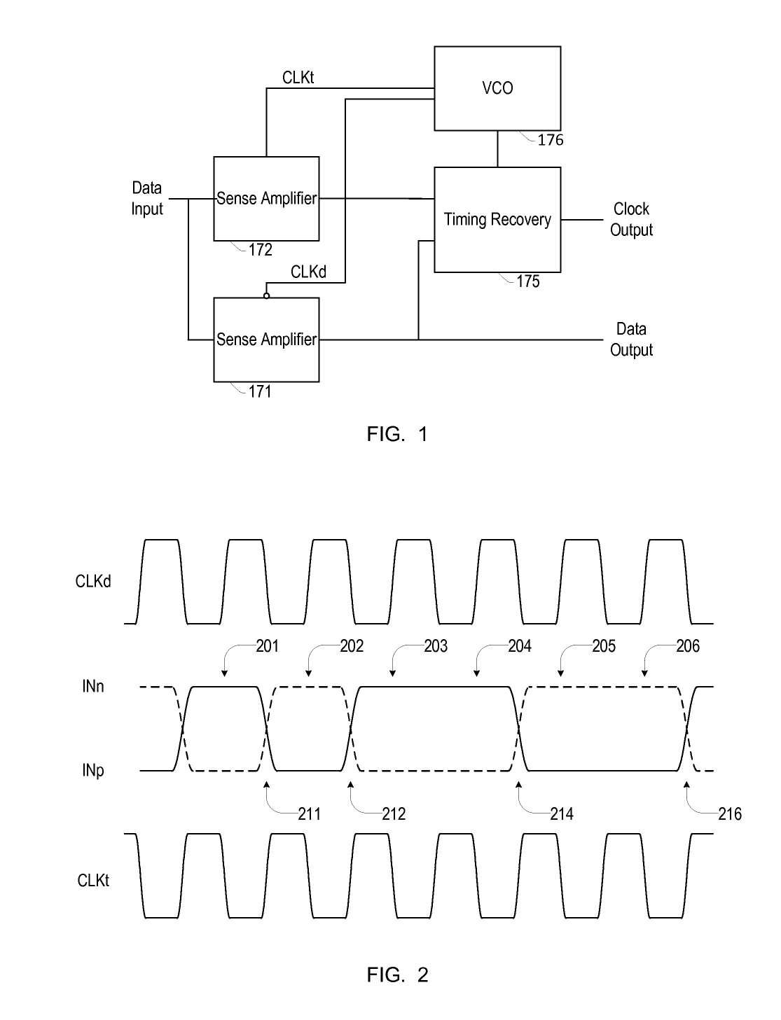

FIG. 1 is a functional block diagram of a clock and data recovery circuit (CDR). The CDR receives a data input signal. The data input signal contains a serial stream of data. The CDR operates to recover the data from the input signal and recover a clock signal that indicates the timing of the data.

The CDR includes a first sense amplifier 171 and a second sense amplifier 172. The first sense amplifier 171 supplies the data output from the CDR. The outputs from the first sense amplifier 171 and the second sense amplifier 172 are used to recover timing from the data input signal. The first sense amplifier 171 samples the data input signal on rising edges of a data clock signal CLKd and produces an output that indicates the sampled value. The second sense amplifier 172 samples the data input signal on rising edges of a timing clock signal CLKt and produces an output that indicates the sampled value. The data input signal and other signals of the CDR may be differential signals.

A timing recovery module 175 receives the output of the first sense amplifier 171 and the output of the second sense amplifier 172, which are sampled at different clock phases. The timing recovery module 175 uses the outputs of the sense amplifiers, for example, based on an Alexander phase detector, to control the frequency of a voltage controlled oscillator (VCO) 176. The VCO 176 supplies the data clock signal CLKd and the timing clock signal CLKt based on the control from the timing recovery module 175. There are many variations of CDRs, in addition to the example CDR of FIG. 1, that may use sense amplifiers as disclosed herein.

FIG. 2 is a waveform diagram illustrating operation of the clock and data recovery circuit of FIG. 1. The waveforms illustrated in FIG. 2 show a differential data input signal that includes a positive input INp and a negative input INn. The data clock signal CLKd and the timing clock signal CLKt are also illustrated in FIG. 2. The illustrated waveforms show a “locked” condition where the timing recovery module 175 has adjusted the timing of the clocks so that the data clock signal CLKd rises at the middle of each bit time of the data input and the timing clock signal CLKt rises at the transition times of the data input.

At a first illustrated time 201, a rising edge of the data clock signal CLKd occurs and the first sense amplifier 171 samples the data input signal. At time 201, the positive input signal INp is greater than the negative input signal INn, which is the condition for a ONE data value. Accordingly, the first sense amplifier 171 will produce a ONE on its output. The time delay from when the sense amplifier is triggered by the clock signal to when the output of the sense amplifier is available may be termed the delay or resolving time of the sense amplifier. It is generally desirable for the resolving time to be less than a clock period. The first sense amplifier 171 operates in a similar manner at its subsequent sampling times (202, 203, 204, 205, 206).

At a second illustrated time 211, a rising edge of the timing clock signal CLKt occurs and the second sense amplifier 172 samples the data input signal. At time 211, the positive input signal INp and the negative input signal INn are transitioning and at approximately the same level. In this situation, the resolving time of the second sense amplifier 172 may be long. A long resolving time may be due to the differential input signal level having a small magnitude. A long resolving time may also be due to the input signal transitioning during the resolving time. For example, a sense amplifier may begin resolving towards one value and then transition to the other value. The resolving time of the second sense amplifier 172 may also be extended at subsequent sampling times (212, 214, 216).

When the resolving time of the sense amplifier is long, errors can result in operation of the CDR. Accordingly, the sense amplifiers used in the CDR have resolving times that are improved over conventional sense amplifiers. Whether the second sense amplifier 172 resolves to a ONE value or in ZERO value on a given sample may not be critical as the timing recovery module 175 adjusts the VCO 176 using a large number of samples. However, operation of the timing recovery module 175 could be erroneous when a long resolving time causes the output of the sense amplifier to arrive at the time recovery module 175 much later than expected. FIG. 1 illustrates a common CDR arrangement. Similar needs for fast-resolving sense amplifiers exist in other CDRs. The need for fast-resolving amplifiers also exists in other circuits, for example, in pipelined analog-to-digital converters.

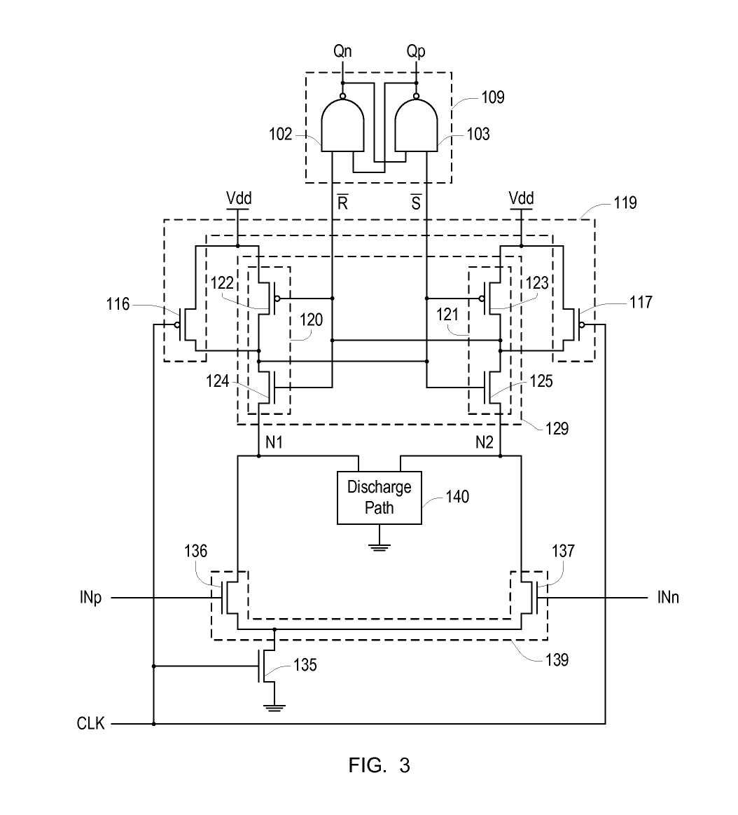

FIG. 3 is a schematic diagram of a sense amplifier according to a presently disclosed embodiment. The sense amplifier may be used, for example, in the CDR of FIG. 1.

The sense amplifier of FIG. 3 receives a differential input signal including a positive input INp and a negative input INn. The sense amplifier operates in two phases: a precharge phase and a resolving phase. During the precharge phase, some nodes in the sense amplifier are initialized. During the resolving phase, the differential input signal is sensed and corresponding values are output by the sense amplifier. The resolving phase may also be termed a sensing or evaluation phase. The sense amplifier of FIG. 3 provides complementary output signals including a positive output Qp and a negative output Qn.

The sense amplifier receives a clock signal CLK. The precharge phase of the sense amplifier occurs while the clock signal CLK is low. The resolving phase of the sense amplifier begins when the clock signal CLK transitions from a low level to a high level. The resolving phase of the sense amplifier ends when the output of the sense amplifier is available.

The sense amplifier includes a first latch 129 that includes a first inverter 120 and a second inverter 121. The first latch 129 produces a set signal S and a reset signal R. The first inverter 120 and the second inverter 121 are cross-coupled with the output of the first inverter 120 connected to the input of the second inverter 121 and the output of the second inverter 121 connected to the input of the first inverter 120. The output of the first inverter 120 produces the set signal S and the output of the second inverter 121 produces the reset signal R.

The first inverter 120 includes a p-channel transistor 122 and an n-channel transistor 124. P-channel transistor 122 has its source connected to a voltage supply Vdd, its gate connected to the reset signal R, and its drain connected to the set signal S. N-channel transistor 124 has its drain connected to the set signal S, its gate connected to the reset signal R, and its source node connected to a first switched ground node N1.

The second inverter 121 includes a p-channel transistor 123 and an n-channel transistor 125. P-channel transistor 123 has its source connected to the voltage supply Vdd, its gate connected to the set signal S, and its drain connected to the reset signal R. N-channel transistor 125 has its drain connected to the reset signal R, its gate connected to the set signal S, and its source connected to a second switched ground node N2.

The sense amplifier includes a second latch 109 that uses the set signal S and the reset signal R from the first latch 129 to produce the complementary output signals. The second latch 109, in the embodiment illustrated in FIG. 3, is a set-reset latch that uses cross-coupled NAND gates. NAND gate 102 logically NANDs the reset signal R and the positive output Qp to produce the negative output Qn. NAND gate 103 logically NANDs the set signal S and the negative output Qn to produce the positive output Qp. The set signal S and the reset signal R are active low, that is, the second latch 109 is set (positive output Qp high and a negative output Qn low) when the set signal S is low and is reset (positive output Qp low and a negative output Qn high) when the reset signal R is low.

During the precharge phase, the set signal S and the reset signal R are precharged to a high level by a precharge circuit 119. The precharge circuit 119 includes p-channel transistor 116 and p-channel transistor 117. P-channel transistor 116 has its source connected to the voltage supply Vdd, its gate connected to the clock signal CLK, and its drain connected to the set signal S. P-channel transistor 117 has its source connected to the voltage supply Vdd, its gate connected to the clock signal CLK, and its drain connected to the reset signal R. When the clock signal CLK is low, the precharge circuit 119 is active and p-channel transistor 116 and p-channel transistor 117 are on and the set signal S and the reset signal R are driven to the voltage of the voltage supply Vdd. When the clock signal CLK is high, the precharge circuit 119 is not active.

A transistor pair 139 couples the differential input signal to the first latch 129. The transistor pair 139 includes n-channel transistor 136 and n-channel transistor 137. N-channel transistor 136 has its drain connected to the first switched ground node N1 (connected to the first inverter 120), its gate connected to the positive input signal INp, and its source connected to a common node. N-channel transistor 137 has its drain connected to the second switched ground node N2 (connected to the second inverter 121), its gate connected to the negative input signal INn, and its source connected to the common node. During the precharge phase, the first switched ground node N1 is precharged (from the set signal S via n-channel transistor 124) and the second switched ground node N2 is precharged (from the reset signal R via n-channel transistor 125). During the resolving phase, the first switched ground node N1 or the second switch ground node N2 can be discharged depending on the differential input signal.

N-channel transistor 135 operates as a switch to couple the common node to a ground reference during the resolving phase. Since n-channel transistor 135 operates as a switch, it may also be termed a switch. N-channel transistor 135 has its drain connected to the common node, its gate connected to the clock signal CLK, and its source connected to the ground reference. The clock signal CLK controls whether n-channel transistor 135 is switched on or switched off and thus may be considered a control of the transistor.

A discharge path circuit 140 is also coupled to the first latch 129 at the first switched ground node N1 and the second switched ground node N2. The discharge path circuit 140 can accelerate the resolving phase of the sense amplifier. The discharge path circuit 140 may use the clock signal CLK, for example, to enable its operation.

Operation of the resolving phase of the sense amplifier will now be described for various conditions. Operations will initially be described ignoring the effect of the discharge path circuit 140. A first condition is when the differential input signal has a large positive value. A large value (e.g., 100 mV) is a value that causes the first latch 129 to quickly (e.g., within 100 ps) switch when driven by the transistor pair 139 and n-channel transistor 135. When the clock signal CLK rises and the resolving phase begins, n-channel transistor 135 is turned on by the high clock signal CLK and the common node is pulled toward ground. The first switched ground node N1 is pulled toward ground more rapidly than the second switched ground node N2 is pulled toward ground due to the higher voltage on the positive input INp compared to the negative input INn. The set signal S is pulled low through n-channel transistor 124 in the first inverter 120, n-channel transistor 136 in the transistor pair 139, and n-channel transistor 135. The reset signal R is held high by p-channel transistor 123 in the second inverter 121. The low level on the set signal S sets the positive output Qp high and the negative output Qn low, which corresponds to the positive value of the differential input signal.

A second condition is when the differential input signal has a large negative value. When the clock signal CLK rises and the resolving phase begins, n-channel transistor 135 is turned on by the high clock signal CLK and the common node is pulled toward ground. The second switched ground node N2 is pulled to ground more rapidly than the first switched ground node N1 is pulled to ground due to the higher voltage on the negative input INn compared to the positive input INp. The reset signal R is pulled low through n-channel transistor 125 in the second inverter 121, n-channel transistor 137 in the transistor pair 139, and n-channel transistor 135. The set signal S is held high by p-channel transistor 122 in the first inverter 120. The low level on the reset signal R sets the negative output Qn high and the positive output Qp low, which corresponds to the negative value of the differential input signal.

A third condition is when the differential input signal has a small positive value. A small value is a value that causes the first latch 129 to slowly switch when driven by the transistor pair 139 and n-channel transistor 135. Slowly switching may be, for example, a switching time that is longer than for comparable to the duration of the high time of the clock signal. When the clock signal CLK rises and the resolving phase begins, n-channel transistor 135 is turned on by the high clock signal CLK and the common node is pulled toward ground. The first switched ground node N1 is pulled toward ground only slightly more rapidly than the second switched ground node N2 is pulled toward ground due to the higher voltage on the positive input INp compared to the negative input INn. The set signal S is pulled low through n-channel transistor 124 in the first inverter 120, n-channel transistor 136 in the transistor pair 139, and n-channel transistor 135. The reset signal R is pulled low through n-channel transistor 125 in the second inverter 121, n-channel transistor 137 in the transistor pair 139, and n-channel transistor 135. The set signal S is pulled high by p-channel transistor 122 in the first inverter 120. The reset signal R is pulled high by p-channel transistor 123 in the second inverter 121.

The set signal S and the reset signal R can remain at intermediate levels (e.g., approximately 450 mV when the voltage supply is 900 mV) for an extended time (e.g., 1 ns). The intermediate levels on the set signal and the reset signal are based on the relative strengths of the pull up paths and pull down paths. The set signal S can eventually switch to a low level and the reset signal to a high-level due to the current through n-channel transistor 136 being greater than the current through n-channel transistor 137. The low level on the set signal S sets the positive output Qp high and the negative output Qn low, which corresponds to the positive value of the differential input signal.

A fourth condition is when the differential input signal is switching from a negative value to a positive value near the beginning of the resolving phase. In this condition, the negative value of the differential input signal will cause the reset signal R to begin to transitioning to a low level. When the differential input signal switches to a positive value, the set signal S will begin transitioning to a low level. However, the lower level on the reset signal R can cause the set signal S to transition slowly. Similar to the third condition, the fourth condition can also result in delayed switching of the output of the sense amplifier.

The delayed switching of the sense amplifier output, for example, as in the third condition and forth condition described above, can cause errors, such as metastability, in a circuit that uses the output. The discharge path circuit 140 can accelerate the resolving phase of the sense amplifier so that the output of the sense amplifier switches sooner. This can avoid problems associated with delayed switching of the output. The discharge path circuit 140 may increase the switching speed of the first latch 129, for example, by increasing the current available to n-channel transistor 124 of the first inverter 120 and to n-channel transistor 125 of the second inverter 121. The discharge path circuit 140 may begin to accelerate the resolving phase of the sense amplifier after an initial sensing time. The initial sensing time may be, for example, based on the switching time of the set signal S and the reset signal R when the magnitude of the differential input signal is large.

Additionally, when the common mode voltage of the differential input signal is at a midlevel (e.g., 450 mV with a 900 mV supply voltage), n-channel transistor 136 and n-channel transistor 137 of the transistor pair 139 are only weakly on (the excess gate voltage V_{GS}-V_{T} is small) and the discharge of the set signal S or the reset signal R will be slow. The discharge path circuit 140 can provide a relatively strong discharge path so that the set signal S or the reset signal R can be more rapidly pulled low.

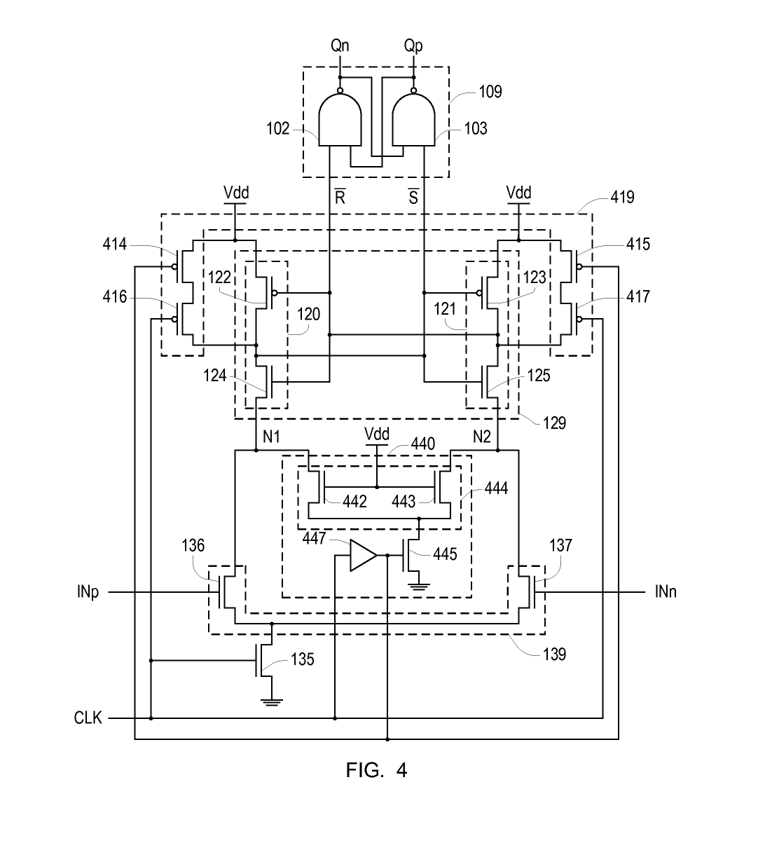

FIG. 4 is a schematic diagram of another sense amplifier according to a presently disclosed embodiment. The sense amplifier of FIG. 4 is similar to the sense amplifier of FIG. 3 with like referenced elements operating in like fashion except for described differences. The sense amplifier may be, for example, used in the clock and data recovery circuit of FIG. 1.

The sense amplifier of FIG. 4 includes a discharge path circuit 440 that can accelerate the resolving phase of the sense amplifier. The discharge path circuit 440 uses the clock signal CLK, for example, to time its operation. The discharge path circuit 440 includes a second transistor pair 444. The second transistor pair 444 includes n-channel transistor 442 and n-channel transistor 443. N-channel transistor 442 has its drain connected to the first switched ground node N1, its gate connected to the voltage supply Vdd, and its source connected to a second common node. N-channel transistor 443 has its drain connected to the second switched ground node N2, its gate connected to the voltage supply Vdd, and its source connected to the second common node.

The discharge path circuit 440 includes n-channel transistor 445 that operates as a switch to couple the second common node to the ground reference during the resolving phase. Since n-channel transistor 445 operates as a switch, it may also be termed a switch. N-channel transistor 445 has its drain connected to the second common node, its gate connected to a delayed clock signal, and its source connected to the ground reference. The delayed clock signal controls whether n-channel transistor 445 is switched on or switched off and thus may be considered a control of the transistor. A delay element 447 produces the delayed clock signal as a copy of the clock signal CLK delayed by a delay time. The delay element 447, for example, may use a chain of inverters.

The delay time of the delay element 447 causes n-channel transistor 445 (and the discharge path circuit 440) to turn on the delay time after n-channel transistor 135 is turned on. The delay time may, for example, correspond to a resolving time of the first latch 129 when the voltage of the differential input signal is large. The delay time may alternatively or additionally correspond to a resolving time of the sense amplifier when the differential input signal is large. The differential input signal may be considered large, for example, when its magnitude is sufficient to cause the sense amplifier to switch sufficiently fast for the circuit in which the sense amplifier is used. The delay time of the delay element 447 may be adaptively based on a switching speed (resolving time) of the sense amplifier or may be produced by a fixed circuit.

During the precharge phase, the set signal S and the reset signal R are precharged to a high level by a precharge circuit 419. The precharge circuit 419 includes p-channel transistor 414, p-channel transistor 415, p-channel transistor 416, and p-channel transistor 417. P-channel transistor 414 and p-channel transistor 416 are coupled in series between the voltage supply Vdd and the set signal S. P-channel transistor 415 and p-channel transistor 417 are coupled in series between the voltage supply Vdd and the reset signal R. The gates of p-channel transistor 414 and p-channel transistor 415 are connected to the delayed clock signal. The gates of p-channel transistor 416 and p-channel transistor 417 are connected to the clock signal CLK. Using series transistors in the precharge circuit 419 can avoid a direct current path between the voltage supply and the ground reference on transitions of the clock signal CLK. When the clock signal CLK is low and the delayed clock signal is low, the precharge circuit 419 is active and the set signal S and the reset signal R are pulled to the voltage of the voltage supply Vdd. When the clock signal CLK is high or the delayed clock signal is high, the precharge circuit 419 is not active.

Operation of the resolving phase of the sense amplifier of FIG. 4 will now be described for the third condition (the differential input signal has a small positive value) described above with reference to FIG. 3. For clarity, the transistor pair 139 will be referred to as the first transistor pair and the common node of the first transistor pair will be referred to as the first common node.

When the clock signal CLK rises and the resolving phase begins, n-channel transistor 135 is turned on by the high clock signal CLK and the first common node is pulled toward ground. The first switched ground node N1 is pulled toward ground slightly more rapidly than the second switched ground node N2 is pulled toward ground due to the higher voltage on the positive input INp compared to the negative input INn. The set signal S is pulled low through n-channel transistor 124 in the first inverter 120, n-channel transistor 136 in the first transistor pair 139, and n-channel transistor 135. The reset signal R is pulled low through n-channel transistor 125 in the second inverter 121, n-channel transistor 137 in the first transistor pair 139, and n-channel transistor 135. The set signal S is pulled high by p-channel transistor 122 in the first inverter 120. The reset signal R is pulled high by p-channel transistor 123 in the second inverter 121.

A delay time after the clock signal CLK rises, the delayed clock signal rises and switches on n-channel transistor 445, which couples the second common node to the ground reference. This introduces a discharge path for the first switched ground node N1 through n-channel transistor 442 and n-channel transistor 445 and a discharge path for the second switched ground node N2 through n-channel transistor 443 and n-channel transistor 445. When the discharge path circuit 440 is switched on, the first latch will have an increased switching speed and can quickly resolve to a digital logic state. The resolved state of the first latch 129 depends on the differential input signal and the condition of the first latch 129 when the discharge path circuit 440 is switched on. In the third condition, the set signal S is lower than the reset signal R when the discharge path circuit 440 is switched on due to the positive voltage on the differential input signal. Accordingly, the first latch 129 resolves to the set signal S low and the reset signal R high. The low level on the set signal S sets the positive output Qp high and the negative output Qn low, which corresponds to the positive value of the differential input signal.

The discharge path circuit 640 works similarly in other conditions to accelerate the resolving phase of the sense amplifier.

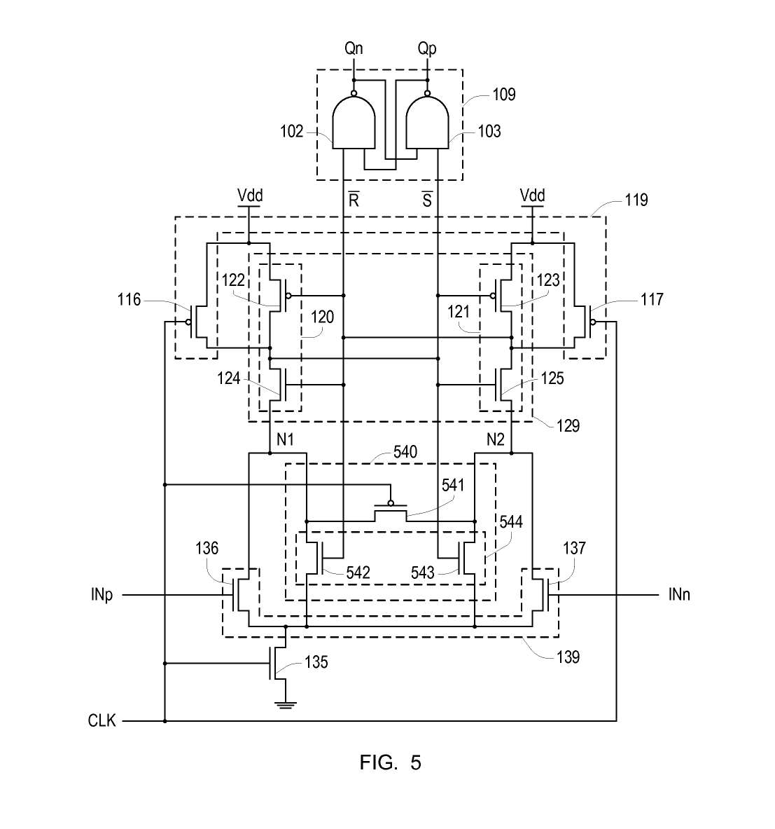

FIG. 5 is a schematic diagram of another sense amplifier according to a presently disclosed embodiment. The sense amplifier of FIG. 5 is similar to the sense amplifier of FIG. 3 with like referenced elements operating in like fashion except for described differences. The sense amplifier may be, for example, used in the clock and data recovery circuit of FIG. 1.

The sense amplifier of FIG. 5 includes a discharge path circuit 540 that can accelerate the resolving phase of the sense amplifier. The discharge path circuit 540 includes a second transistor pair 544. The second transistor pair 544 includes n-channel transistor 542 and n-channel transistor 543. N-channel transistor 542 has its drain connected to the first switched ground node N1, its gate connected to the reset signal R, and its source connected to the common node. N-channel transistor 543 has its drain connected to the second switched ground node N2, its gate connected to the set signal S, and its source connected to the common node. The second transistor pair 544 can improved the resolving time of the sense amplifier, for example, by increasing the current available to the first latch 129.

The discharge path circuit 540 includes p-channel transistor 541 that operates as a switch to couple the first switched ground node N1 and the second switched ground node N2 (which are connected to the drains of the first transistor pair 139 and the drains of the second transistor pair 544) during the precharge phase. Alternatively or additionally, the discharge path circuit 540 may include a p-channel transistor to couple the set signal S and the reset signal R during the precharge phase. Since p-channel transistor 541 operates as a switch, it may also be termed a switch. P-channel transistor 541 has its gate connected the clock signal CLK and its drain and source connected to the first switched ground node N1 and the second switched ground node N2. P-channel transistor 541 is on during the precharge phase of the sense amplifier and off during the resolving phase of the sense amplifier. P-channel transistor 541 equalizes the first switched ground node N1 and the second switched ground node N2. This removes or reduces any remaining decision information (e.g., residual voltage difference between the nodes) from a previous cycle, which could otherwise cause an input offset error voltage.

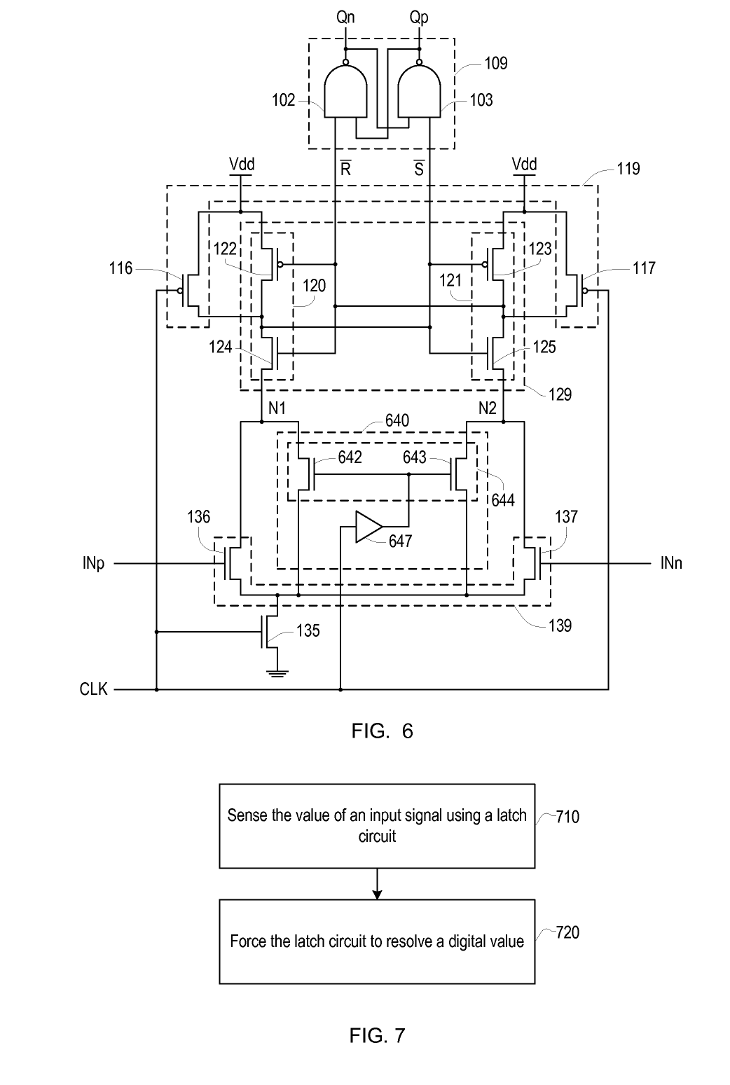

FIG. 6 is a schematic diagram of another sense amplifier according to a presently disclosed embodiment. The sense amplifier of FIG. 6 is similar to the sense amplifier of FIG. 3 with like referenced elements operating in like fashion except for described differences. The sense amplifier may be, for example, used in the clock and data recovery circuit of FIG. 1.

The sense amplifier of FIG. 6 includes a discharge path circuit 640 that can accelerate the resolving phase of the sense amplifier. The discharge path circuit 640 uses the clock signal CLK to time its operation. The discharge path circuit 640 includes a second transistor pair 644. The second transistor pair 644 includes n-channel transistor 642 and n-channel transistor 643. N-channel transistor 642 has its drain connected to the first switched ground node N1, its gate connected to a delayed clock signal, and its source connected to the common node. N-channel transistor 643 has its drain connected to the second switched ground node N2, its gate connected to the delayed clock signal, and its source connected to the common node.

The delayed clock signal controls whether the discharge path circuit 640 is switched on or switched off and thus may be considered a control of the discharge path circuit 640. A delay element 647 produces the delayed clock signal as a copy of the clock signal CLK delayed by a delay time. The delay element 647, for example, may use a chain of inverters.

The delay time of the delay element 647 causes n-channel transistor 642 and n-channel transistor 643 (and the discharge path circuit 640) to turn on the delay time after n-channel transistor 135 is turned on. The delay time may, for example, correspond to a resolving time of the first latch 129 when the voltage of the differential input signal is large. The delay time may alternatively or additionally correspond to a resolving time of the sense amplifier when the differential input signal is large. The differential input signal may be considered large, for example, when its magnitude is sufficient to cause the sense amplifier to switch sufficiently fast for the circuit in which the sense amplifier is used. The delay time of the delay element 647 may be adaptively based on a switching speed (resolving time) of the sense amplifier or may be produced by a fixed circuit.

Operation of the resolving phase of the sense amplifier of FIG. 6 will now be described for the third condition (the differential input signal has a small positive value) described above with reference to FIG. 3. For clarity, the transistor pair 139 will be referred to as the first transistor pair.

When the clock signal CLK rises and the resolving phase begins, n-channel transistor 135 is turned on by the high clock signal CLK and the first common node is pulled toward ground. The first switched ground node N1 is pulled toward ground slightly more rapidly than the second switched ground node N2 is pulled toward ground due to the higher voltage on the positive input INp compared to the negative input INn. The set signal S is pulled low through n-channel transistor 124 in the first inverter 120, n-channel transistor 136 in the first transistor pair 139, and n-channel transistor 135. The reset signal R is pulled low through n-channel transistor 125 in the second inverter 121, n-channel transistor 137 in the first transistor pair 139, and n-channel transistor 135. The set signal S is pulled high by p-channel transistor 122 in the first inverter 120. The reset signal R is pulled high by p-channel transistor 123 in the second inverter 121.

A delay time after the clock signal CLK rises, the delayed clock signal rises and switches on n-channel transistor 642 and n-channel transistor 643. This introduces a discharge path for the first switched ground node N1 through n-channel transistor 642 and n-channel transistor 135 and a discharge path for the second switched ground node N2 through n-channel transistor 643 and n-channel transistor 135. When the discharge path circuit 640 is switched on, the first latch will have an increased switching speed and can quickly resolve to a digital state. The resolved state of the first latch 129 depends on the differential input signal and the condition of the first latch 129 when the discharge path circuit 640 is switched on. In the third condition, the set signal S is lower than the reset signal R when the discharge path circuit 640 is switched on due to the positive voltage on the differential input signal. Accordingly, the first latch 129 resolves to the set signal S low and the reset signal R high. The low level on the set signal S sets the positive output Qp high and the negative output Qn low, which corresponds to the positive value of the differential input signal.

The discharge path circuit 640 works similarly in other conditions to accelerate the resolving phase of the sense amplifier.

FIG. 7 is a flowchart of a process for sensing an input signal according to a presently disclosed embodiment. The process of FIG. 3 may be performed with various circuits; however, to provide specific examples, the process will be described with reference to the sense amplifiers described above.

In step 710, the value of an input signal is sensed using a latch circuit. For example, the transistor pair 139 and the first latch 129 of the sense amplifier of FIG. 3 can be used to sense the value between the positive input signal INp and the negative input signal INn. Step 710 may be triggered by a signal, for example, the clock signal CLK of the sense amplifiers described above. The latch circuit may produce set and reset signals that are used to produce corresponding output signals.

In step 720, the latch circuit is forced to resolve a digital value. The latch circuit may be forced to resolve a digital value by increasing the switching speed of the latch circuit. Step 720 may begin an initial sensing time after step 710 begins. Forcing the latch circuit to resolve a digital value may include using a discharge path circuit to increase the current available to the latch circuit. Step 720 may use, for example, the discharge path circuit 140 of the sense amplifier of FIG. 3, the discharge path circuit 440 of the sense amplifier of FIG. 4, the discharge path circuit 540 of the sense amplifier of FIG. 5, or the discharge path circuit 640 of the sense amplifier of FIG. 6.

The process of FIG. 7 may be modified, for example, by adding or altering steps. Additionally, the steps may be performed concurrently.

Although embodiments of the invention are described above for particular embodiments, many variations of the invention are possible, including, for example, those with different signal polarities or with additional amplification or latching stages. Additionally the embodiments have been described for CMOS technology but similar circuits may be used with other technologies. Additionally, features of the various embodiments may be combined in combinations that differ from those described above. Although the sense amplifiers have been described as operating with differential input signals they may also be used with pseudo-differential signals (e.g., a differential signal pair with one signal of the pair being a fixed or reference level).

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent presently preferred embodiments of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. A sense amplifier, comprising:
a first latch comprising a first inverter having an output coupled to a set signal and an input coupled to a reset signal and a second inverter having an output coupled to the reset signal and an input coupled to the set signal;
a first transistor pair having gates coupled to a differential input signal, having drains coupled to the first latch, and having sources coupled to a first common node;
a first switch coupled between the first common node and a ground reference, wherein the first switch is configured to be turned off during a precharge phase of the sense amplifier and turned on during a resolving phase of the sense amplifier; and
a discharge path circuit coupled to the drains of the first transistor pair and configured to accelerate the resolving phase of the sense amplifier.

2. The sense amplifier of claim 1, further comprising a second latch configured to produce an output of the sense amplifier based on the set signal and the reset signal.

3. The sense amplifier of claim 1, further comprising a precharge circuit configured to precharge the set signal and the reset signal during the precharge phase of the sense amplifier.

4. The sense amplifier of claim 1, wherein the discharge path circuit comprises:
a second transistor pair having gates coupled to a voltage supply, having drains coupled to the drains of the first transistor pair, and having sources coupled to a second common node; and
a second switch coupled between the second common node and the ground reference, wherein the second switch is configured to be turned off during the precharge phase and turned on during the resolving phase of the sense amplifier.

5. The sense amplifier of claim 4, wherein the discharge path circuit further comprises a delay element configured to turn on the second switch a delay time after the first switch is turned on.

6. The sense amplifier of claim 5, wherein the delay time corresponds to a resolving time of the sense amplifier when the magnitude of the differential input signal is larger than a predetermined amount.

7. The sense amplifier of claim 4, further comprising a precharge circuit configured to precharge the set signal and the reset signal based on a control of the first switch and a control the second switch.

8. The sense amplifier of claim 1, wherein the discharge path circuit comprises a second transistor pair having gates coupled to the set signal and the reset signal, having drains coupled to the drains of the first transistor pair, and having sources coupled to the first common node.

9. The sense amplifier of claim 8, further comprising a second switch coupled between the drains of the first transistor pair, the second switch configured to be off during the resolving phase of the sense amplifier and on during the precharge phase of the sense amplifier.

10. The sense amplifier of claim 1, wherein the discharge path circuit comprises:
a second transistor pair having drains coupled to the drains of the first transistor pair, and having sources coupled to the first common node; and
a delay element configured to turn on the second transistor pair a delay time after the first switch is turned on.

11. A method for sensing an input signal, the method comprising:
sensing a value of the input signal using a latch circuit; and
forcing, after an initial sensing time, the latch circuit to resolve a digital value.

12. The method of claim 11, wherein the latch circuit includes cross-coupled inverters for producing a set signal and a reset signal;
a transistor pair for coupling the input signal to the cross-coupled inverters; and
a switch coupled to the transistor pair for causing the sensing.

13. The method of claim 12, further comprising producing an output signal based on the set signal and the reset signal.

14. The method of claim 12, wherein the step of forcing includes increasing the switching speed of the latch circuit.

15. The method of claim 12, wherein the step of forcing uses a discharge path circuit coupled to the transistor pair and the cross-coupled inverters, the discharge path circuit switched on after the initial sensing time.

16. The method of claim 11, wherein the initial sensing time corresponds to a resolving time of the latch circuit when the magnitude of the input signal is larger than a predetermined amount.

17. A sense amplifier receiving a differential input signal and producing an output, comprising:
a first latch comprising a first inverter and a second inverter having an output coupled to a reset signal and an input of the first inverter and an input coupled to a set signal and an output of the first inverter;
a second latch having an output coupled to the output of the sense amplifier, the second latch being set by the set signal and reset by the reset signal;
a first transistor pair having gates coupled to the differential input signal of the sense amplifier, having drains coupled to the first latch, and having sources coupled to a common node;
a first switch coupled between the common node and a ground reference, wherein the first switch is configured to be turned off during a precharge phase of the sense amplifier and turned on during a resolving phase of the sense amplifier; and
a means for accelerating the resolving phase of the sense amplifier.

18. The sense amplifier of claim 17, wherein the means for accelerating comprises:
a second transistor pair having gates coupled to a voltage supply, having drains coupled to the drains of the first transistor pair, and having sources coupled to a second common node; and
a second switch coupled between the second common node and the ground reference, wherein the second switch is configured to be turned off during the precharge phase and turned on during the resolving phase of the sense amplifier.

19. The sense amplifier of claim 18, wherein the means for accelerating further comprises a delay element configured to turn on the second switch a delay time after the first switch is turned on.

20. The sense amplifier of claim 19, wherein the delay time corresponds to a resolving time of the sense amplifier when the magnitude of the differential input signal is larger than a predetermined amount.
